(19) United States
(12) Patent Application Publication
(10) Pub. No.: US 2024/0412793 A1
(43) Pub. Date: Dec. 12, 2024

(54) NON-VOLATILE MEMORY AND PROGRAMMING METHOD THEREOF

(71) Applicant: MACRONIX International Co., Ltd., Hsinchu (TW)

(72) Inventors: Ya-Jui Lee, Taichung City (TW); Kuan-Fu Chen, Taipei City (TW)

(21) Appl. No.: 18/329,583

(22) Filed: Jun. 6, 2023

(51) Int. Cl. G11C 16/34; G11C 16/10; G11C 16/26

(52) U.S. Cl. CPC G11C 16/3459; G11C 16/102; G11C 16/26

(57) ABSTRACT

A non-volatile memory and a programming method thereof are provided. The programming method includes: performing a reading operation on a plurality of first memory cells of an Nth word line, and determining whether an equivalent threshold voltage is greater than a preset threshold value to generate a determination result, where N is a positive integer greater than 0; and in response to performing a programming operation on a plurality of second memory cells of an N+1th word line, deciding whether to adjust at least one selected programming verification voltage of a plurality of programming verification voltages by an offset value according to the determination result.

### BACKGROUND

### Technical Field

The disclosure relates to a non-volatile memory and a programming method thereof.

### Description of Related Art

In recent years, mobile electronic devices such as tablet computers, notebook computers, smartphones, and solid-state drives have begun to use NAND flash memories as the primary data storage media. Therefore, the demand for low-cost and high-density NAND flash memories is growing rapidly. In order to overcome the problem of reduction in sizes of flash memory cells, various types of flash memory cells with three-dimensional stacked charge trapping layers have been proposed.

However, as the spacings in the memory cells decrease, the lateral transfer of charges between the memory cells severely reduces data retention. Meanwhile, disposing more layers in the memory cells also leads to higher resistance and causes overdrive problems.

### SUMMARY

The disclosure provides a non-volatile memory and a programming method thereof.

The programming method according to an embodiment of the disclosure includes: performing a reading operation on a plurality of first memory cells of an Nth word line, and determining whether an equivalent threshold voltage of the first memory cells is greater than a preset threshold value to generate a determination result, where N is a positive integer greater than 0; and deciding whether to adjust at least one selected programming verification voltage of a plurality of programming verification voltages by an offset value according to the determination result in response to performing a programming operation on a plurality of second memory cells of an N+1th word line.

The non-volatile memory according to an embodiment of the disclosure includes a memory cell array and a controller. The memory cell array includes a plurality of memory cell strings, and each of the memory cell strings is coupled to a plurality of word lines. The controller is coupled to the memory cell array and is configured to: perform a reading operation on a plurality of first memory cells of an Nth word line, and determine whether an equivalent threshold voltage of the first memory cells is greater than a preset threshold value to generate a determination result, where N is a positive integer greater than 0; and decide whether to adjust at least one selected programming verification voltage of a plurality of programming verification voltages by an offset value according to the determination result in response to performing a programming operation on a plurality of second memory cells of an N+1th word line.

Based on the above, in the non-volatile memory according to an embodiment of the disclosure, when a programming operation is performed on the memory cells of the current word line, the state of the threshold voltage of the memory cells of the previous word line may be read.

Then, whether to adjust the programming verification voltage in the programming operation for the memory cells of the current word line is decided according to the equivalent threshold voltage of the memory cells of the previous word line. Through the adjusting operation of the programming verification voltage as described above, the overdrive phenomenon generated in the programming operation of the non-volatile memory can be improved. Further, when the data stored in the memory cells decays, the threshold voltage distribution of the memory cells can be more tightened to effectively improve data retention.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flowchart showing a programming method of a non-volatile memory according to an embodiment of the disclosure.

FIG. 2 is a flowchart showing a programming method of a non-volatile memory according to another embodiment of the disclosure.

FIG. 3 is a schematic diagram showing a programming operation of a non-volatile memory according to an embodiment of the disclosure.

FIG. 4A and FIG. 4B are schematic diagrams showing a distribution state of memory cells after a programming operation of a non-volatile memory according to an embodiment of the disclosure.

FIG. 5 is a schematic diagram showing an adjusting operation performed for a programming verification voltage in a non-volatile memory according to an embodiment of the disclosure.

FIG. 6 is a schematic diagram of a non-volatile memory according to an embodiment of the disclosure.

FIG. 7 is a schematic diagram showing a memory cell string in a non-volatile memory according to an embodiment of the disclosure.

### DETAILED DESCRIPTION OF DISCLOSED EMBODIMENTS

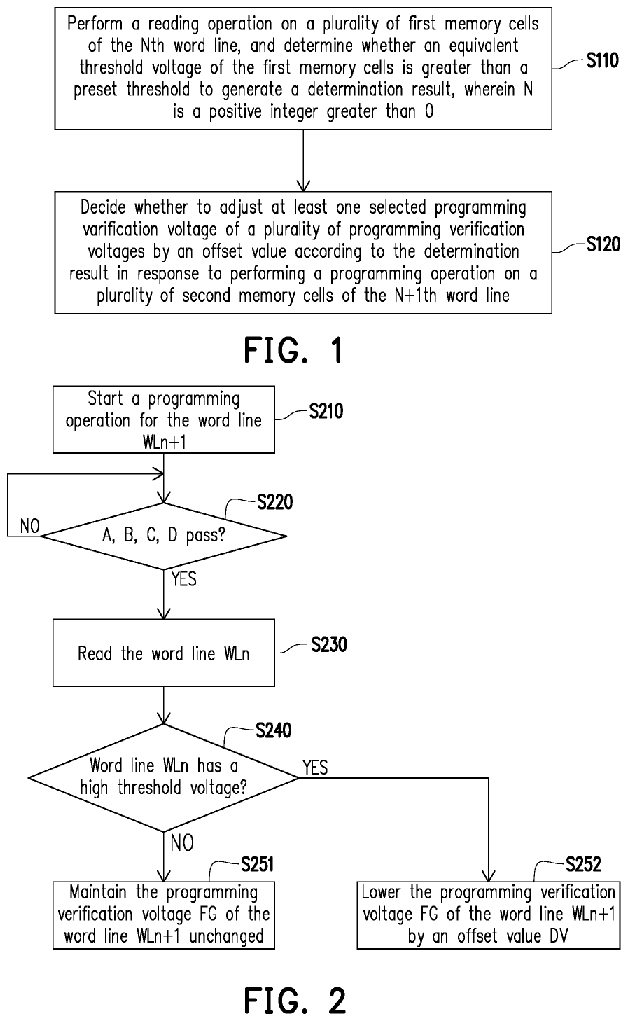

Referring to FIG. 1, FIG. 1 is a flowchart showing a programming method of a non-volatile memory according to an embodiment of the disclosure. In step S110, a reading operation is performed on a plurality of memory cells of an Nth word line for which a programming operation has been completed, and a determination result is generated by determining whether an equivalent threshold voltage of the memory cells of the Nth word line is greater than a preset threshold value or not. The memory cells of the Nth word line may have been programmed respectively to corresponding different logic values. When a programming operation is performed on an N+1th word line, a reading operation may be performed on the memory cells of the Nth word line, so as to obtain the equivalent threshold voltage of the memory cells of the Nth word line, wherein N is a positive integer greater than 0.

In detail, a controller of the non-volatile memory may perform a reading operation on a plurality of memory cells on the Nth word line. A sense amplifier of the non-volatile memory may compare current on bit lines of the memory cells on the Nth word line with a reference current to obtain a comparison result. In this way, the controller may determine whether the equivalent threshold voltage of the memory cells on the Nth word line is at a high threshold voltage state or a low threshold voltage state according to the comparison result.

Specifically, when the comparison result indicates that the read current is less than the reference current, it means that the equivalent threshold voltage of a plurality of memory cells on the Nth word line is greater than the preset threshold value. That is, a plurality of memory cells on the Nth word line have a high equivalent threshold voltage (a high threshold voltage state). On the contrary, when the comparison result indicates that the read current is not less than the reference current, it means that the equivalent threshold voltage of a plurality of memory cells on the Nth word line is not greater than the preset threshold value. That is, a plurality of memory cells on the Nth word line have a low equivalent threshold voltage (a low threshold voltage state).

In step S120, when a programming operation is performed on a plurality of memory cells of an N+1th word line, whether to adjust at least one selected programming verification voltage of a plurality of programming verification voltages by an offset value may be decided according to the determination result generated in step S110. In detail, when a programming operation is performed on a plurality of memory cells of the N+1th word line, a plurality of programming verification voltages respectively corresponding to a plurality of logic values may be set. When the comparison result obtained in step S110 indicates that the equivalent threshold voltage of the memory cells of the Nth word line is greater than the preset threshold value, the controller of the non-volatile memory may set one or more of the programming verification voltages as the selected programming verification voltage, and lower at least one selected programming verification voltage corresponding to the N+1 word line by an offset value.

Then, the controller may perform a programming operation and a programming verification operation on the memory cells of the N+1th word line according to the adjusted programming verification voltage.

On the contrary, if the comparison result obtained in step S110 indicates that the equivalent threshold voltage of the memory cells of the Nth word line is not greater than the preset threshold value, the controller of the non-volatile memory does not adjust all the programming verification voltages set, and performs a programming operation and a programming verification operation on the memory cells of the N+1th word line.

In this embodiment, the programming operation of the non-volatile memory may reduce the programming verification voltage for the programming verification operation of the memory cells of the current word line according to the threshold voltage state of the memory cells of the previous word line. In this way, a phenomenon of insufficient driving current of memory cells on unselected word lines can be avoided. In addition, the programming verification voltage set corresponding to the state of the threshold voltage of the memory cells of the adjacent word line can also effectively improve the data retention and the accuracy of the stored data.

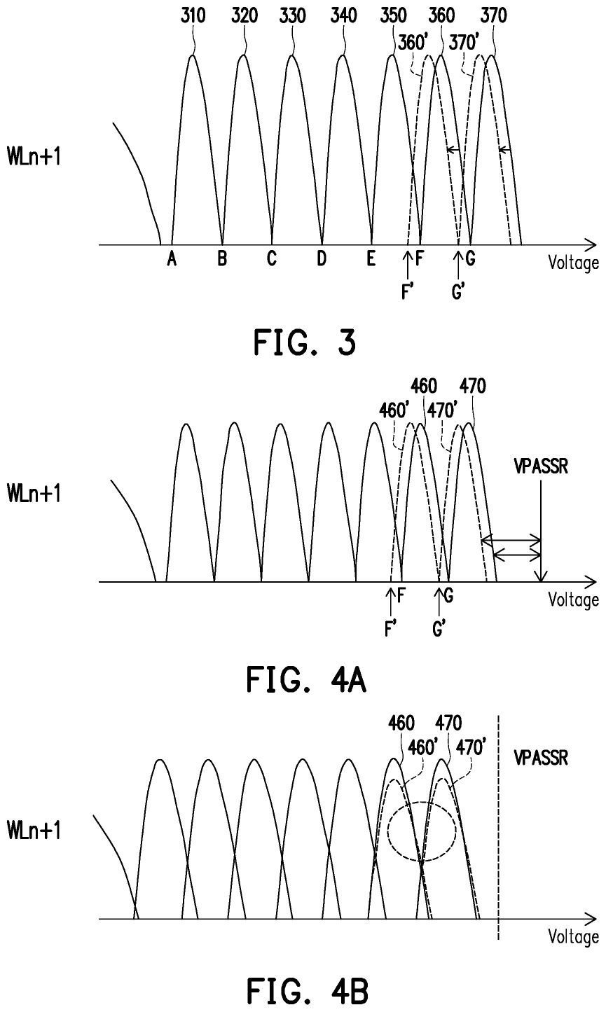

Referring to FIG. 2 below, FIG. 2 is a flowchart showing a programming method of a non-volatile memory according to another embodiment of the disclosure. In this embodiment, the non-volatile memory may be a NAND flash memory. In step S210, a programming operation for an N+1th word line WLn+1 is started. Hereinafter, also referring to FIG. 3 which is a schematic diagram of a programming operation of a non-volatile memory according to an embodiment of the disclosure, in the programming operation of the N+1th word line WLn+1, a plurality of programming verification voltages A, B, C, D, E, F, and G respectively corresponding to a plurality of logic values are set, wherein the programming verification voltages satisfy A<B<C<D<E<F<G. In step S220, a programming verification operation is performed on some memory cells of the N+1th word line WLn+1 to determine whether the memory cells 310, 320, 330, and 340 respectively pass the programming verification voltages A, B, C, and D. If the memory cells 310, 320, 330, and 340 respectively pass the programming verification operation of the programming verification voltages A, B, C, and D, step S230 may be executed. On the contrary, if the memory cells 310, 320, 330, and 340 fail to pass the programming verification voltages A, B, C, and D, the programming operation and the programming verification operation for the memory cells 310, 320, 330, and 340 may be performed again.

In step S230, a reading operation may be performed on the memory cells of an Nth word line WLn, so as to determine the equivalent threshold voltage of the memory cells of the Nth word line WLn. Regarding the equivalent threshold voltage of the memory cells of the Nth word line WLn, by performing a reading operation on all the memory cells of the word line WLn to obtain a reading current, and comparing the reading current with a preset reference current, the equivalent threshold voltage of the memory cells of the Nth word line WLn is in a high threshold voltage state or a low threshold voltage state can be determined.

In step S240, whether the equivalent threshold voltage of the word line WLn is in a high threshold voltage state is determined. If the word line WLn is in a high threshold voltage state, step S252 is executed. On the contrary, if the word line WLn is in a low threshold voltage state, step S251 is executed.

In step S251, the controller may maintain the values of the programming verification voltages E, F, and G unchanged. In step S252, the controller selects the programming verification voltages F and G as the selected programming verification voltages. The controller adjusts the programming verification voltages F and G, and lowers the programming verification voltages F and G by an offset value DV to respectively generate the adjusted programming verification voltages F′ and G′. Then, the controller may perform a programming operation and a programing verification operation on the memory cell 350 according to the programming verification voltage E, perform a programming operation and a programing verification operation on the memory cell 360′ according to the adjusted programming verification voltage F′, and perform a programming operation and a programing verification operation on the memory cell 370′ according to the adjusted programming verification voltage G′.

It is worth noting that, through the adjusting operation for the programming verification voltage, the voltage value of the threshold voltage of the memory cell 360′ is lower than the voltage value of the threshold voltage of the memory cell 360 programmed according to the unadjusted programming verification voltage F.

It should be noted here that, due to the size limit of the cache space in the non-volatile memory, in step S220, the programming verification operation for some memory cells (for example, memory cells 310, 320, 330, and 340) in the word line WLn+1 is completed first. In order to perform the reading operation for the equivalent threshold voltage of the memory cells of the word line WLn, a cache space of a certain size is required. Therefore, the programming verification operation for some of the memory cells in the word line WLn+1 is completed first in step S220, so as to release a sufficient size of the cache space for performing the reading operation of the equivalent threshold voltage of the memory cells of the word line WLn.

Therefore, in step S220, the number of some memory cells in the word line WLn+1 for which the programming verification operation is completed first may be set according to the size of the cache space in the non-volatile memory. Specifically, when the size of the cache space in the non-volatile memory is large enough, the controller may execute step S230 after the programming verification operation corresponding to the programming verification voltage A is completed in step S220. Alternatively, the controller may execute step S230 after the programming verification operations corresponding to the programming verification voltages A and B are completed or after the programming verification operations corresponding to the programming verification voltages A, B, and C are completed in step S220. When the size of the cache space in the non-volatile memory is not large enough, the controller may also execute step S230 after the programming verification operations corresponding to the programming verification voltages A, B, C, D, and E are completed in step S220.

Further, in step S252, the number of programming verification voltages selected to be adjusted may be changed. The designer may select only the highest programming verification voltage G for adjustment, select the programming verification voltages G and F for adjustment, or select more programming verification voltages G, F, and E (or more) for adjustment without particular limitations. The designer may decide the number of programming verification voltages to be adjusted according to the distribution range of the programming verification voltages A to G and the adjustable space.

The value of the offset voltage DV may be set according to the data decay of the memory cells caused by the attraction of the charges in the memory cells of the adjacent word lines in the non-volatile memory. The above-mentioned data decay may be obtained by testing an actual non-volatile memory.

It should be noted here that, when the memory cells of the Nth word line WLn are in a high threshold voltage state, it means that the memory cells of the word line WLn have less influence on the memory cells of the N+1th word line WLn+1. Under such conditions, the controller of the non-volatile memory in the embodiment of the disclosure first lowers some of the programming verification voltages of the memory cells of the N+1th word line WLn+1 during the programming operation. When the memory cells in the remaining word lines encounter data decay due to influence from the memory cells in the adjacent word lines, it results in an overlap with the adjusted distribution range of the memory cells in the N+1th word line WLn+1, which effectively improves data retention.

Referring to FIG. 4A and FIG. 4B below, FIG. 4A and FIG. 4B are schematic diagrams showing the distribution state of the memory cells after the programming operation of the non-volatile memory according to an embodiment of the disclosure. It can be clearly seen from FIG. 4A that, by respectively lowering the programming verification voltages F and G to F′ and G′, the distribution of the threshold voltages of the memory cells 460′ and 470′ is moved toward the low voltage direction, and the distance between the maximum threshold voltage of the memory cell 470′ and the pass voltage VPASSR is increased. That is, through the programming operation of the disclosure, the equivalent resistance of the memory cell string formed by the memory cells in the word line WLn can be reduced, and the overdrive operation of the memory cells in the programming operation can be improved.

In FIG. 4B, after data decay occurs, the adjusted threshold voltage distribution range of the memory cells 460′ and 470′ overlaps with the threshold voltage distribution range of the memory cells after decay, and a threshold voltage distribution range of the memory cells 460 and 470 with a relatively high degree of cohesion is formed, which effectively improves the data retention of the non-volatile memory.

It should be noted that, regarding the curves in FIG. 3, FIG. 4A, and FIG. 4B, the vertical axis represents the number of memory cells.

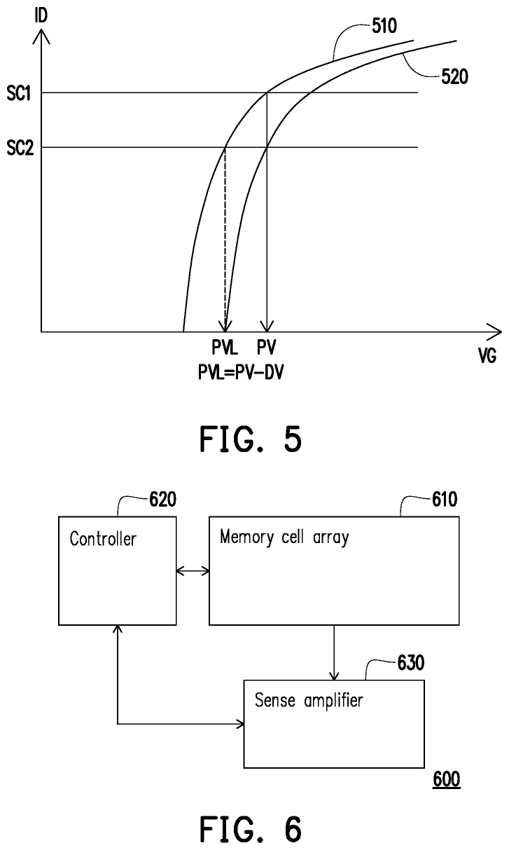

Referring to FIG. 5 below, FIG. 5 is a schematic diagram showing an adjusting operation performed for a programming verification voltage in a non-volatile memory according to an embodiment of the disclosure. In FIG. 5, during a memory cell programming operation, a relation curve of current ID and voltage VG can be moved according to, for example the direction from a curve 510 forward to a curve 520.

When a programming verification voltage of a programming verification operation is adjusted, a word line voltage of a memory cell needs to be adjusted. Such as that, it will cost extra time because of re-discharge and recharge operations performed on the word line of the memory cell.

Based on the above, when the programming verification voltage PV needs to be adjusted to an adjusted programming verification voltage PVL, wherein there is an offset value DV between the adjusted programming verification voltage PVL and the programming verification voltage PV, the controller may keep a word line voltage of the memory cell at the programming verification voltage PV, and perform a programming verification operation by comparing a current of the memory cell with a reference current SC1. At this time, a characteristic curve of the memory cell is the curve 510, the reference current SC1 can be determined according to the curve 510 and the programming verification voltage PV.

At this condition, the programming verification operation is equivalent to a programming verification operation according to the adjusted programming verification voltage PVL and a reference current SC2, wherein the reference current SC2 is determined according to the curve 520 and the programming verification voltage PV. That is, in present embodiment, the programming verification operation according to the adjusted programming verification voltage PVL can be effectively completed without adjusting the word line voltage of the memory cell, and an operation speed of the programming verification operation can be improved.

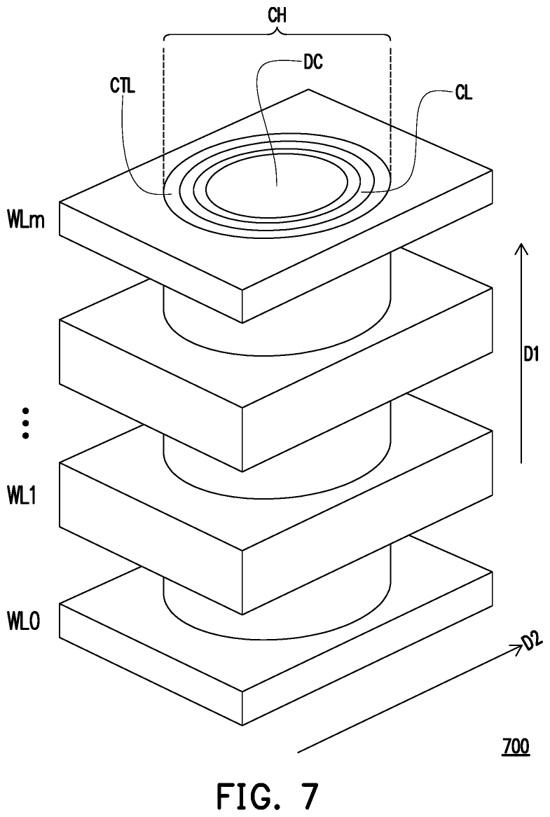

Referring to FIG. 6 below, FIG. 6 is a schematic diagram of a non-volatile memory according to an embodiment of the disclosure. The non-volatile memory 600 includes a memory cell array 610, a controller 620, and a sense amplifier 630. The memory cell array 610 may include a plurality of memory cell strings, and each memory cell string is coupled to a plurality of word lines. The memory cell string may be a NAND flash memory cell string. The controller 620 is coupled to the memory cell array 610. The controller 620 may be configured to perform each step of the programming operation described in the previous embodiments. The sense amplifier 630 is coupled to the memory cell array 610 and may be configured to perform data reading and the programming verification operation of the memory cell array 610.

The controller 610 may be a processor with computing capability. Alternatively, the controller 610 may be a hardware circuit designed based on a hardware description language (HDL) or any other digital circuit design methods well known to those skilled in the art, and realized by Field Programmable Gate Array (FPGA), Complex Programmable Logic Device (CPLD), or Application-specific Integrated Circuit (ASIC).

The sense amplifier 630 may be implemented by using a sense amplifying circuit well known to those skilled in the art without particular limitations.

Referring to FIG. 7 below, FIG. 7 is a schematic diagram showing a memory cell string in a non-volatile memory according to an embodiment of the disclosure. The memory cell string 700 includes a dielectric core DC, a channel layer CL, a charge trapping layer CTL, and word lines WL0 to WLm formed by a plurality of metal layers. The channel layer CL is made of, for example, polysilicon and is used to surround the dielectric core DC, and the charge trapping layer CTL surrounds the channel layer CL. The dielectric core DC, the channel layer CL, and the charge trapping layer CTL extend along the direction D1 and form a columnar channel structure CH. The word lines WLO to WLm extend along the direction D2 and are respectively coupled to a plurality of parts of the columnar channel structure CH to form a plurality of memory cells. Memory cells in the same columnar channel structure CH form a memory cell string.

To sum up, in the non-volatile memory according to an embodiment of the disclosure, when a programming operation is performed on the current word line, the memory cells of the previous word line may be read to obtain the equivalent threshold voltage state of the memory cells of the previous word line, and some of the programming verification voltages in the programming operation for the current word line are adjusted according to the equivalent threshold voltage state of the memory cells of the previous word line. Thereby, the overdrive state and data retention of the non-volatile memory can be improved to enhance the overall performance of the non-volatile memory.

What is claimed is:

1. A programming method, adapted for a non-volatile memory, comprising:
performing a reading operation on a plurality of first memory cells of an Nth word line, and determining whether an equivalent threshold voltage of the first memory cells is greater than a preset threshold value to generate a determination result, wherein N is a positive integer greater than 0; and
deciding whether to adjust at least one selected programming verification voltage of a plurality of programming verification voltages by an offset value according to the determination result in response to performing a programming operation on a plurality of second memory cells of an N+1th word line.

2. The programming method according to claim 1, wherein a programming operation for a first part of the second memory cells of the N+1th word line is completed before performing the reading operation on the first memory cells of the Nth word line.

3. The programming method according to claim 1, wherein performing the reading operation on the first memory cells of the Nth word line, and determining whether the equivalent threshold voltage of the first memory cells is greater than the preset threshold value to generate the determination result comprises:
reading the first memory cells of the Nth word line by comparing current on bit lines of the first memory cells with a reference current to obtain whether the equivalent threshold voltage of the first memory cells is at a high threshold voltage state or a low threshold voltage state.

4. The programming method according to claim 3, wherein if the equivalent threshold voltage of the first memory cells is greater than the preset threshold value, the equivalent threshold voltage is at the high threshold voltage state; and if the equivalent threshold voltage of the first memory cells is not greater than the preset threshold value, the equivalent threshold voltage is at the low threshold voltage state.

5. The programming method according to claim 1, wherein deciding whether to adjust the at least one selected programming verification voltage of the programming verification voltages by the offset value according to the determination result comprises:
lowering the at least one selected programming verification voltage of the programming verification voltages by the offset value in response to the equivalent threshold voltage of the first memory cells being greater than the preset threshold value.

6. The programming method according to claim 5, wherein deciding whether to adjust the at least one selected programming verification voltage of the programming verification voltages by the offset value according to the determination result further comprises:
maintaining the at least one selected programming verification voltage of the programming verification voltages unchanged in response to the equivalent threshold voltage of the first memory cells being not greater than the preset threshold value.

7. The programming method according to claim 2, further comprising:
performing a programming operation on a second part of the second memory cells of the N+1th word line according to at least one adjusted programming verification voltage.

8. The programming method according to claim 7, wherein a threshold voltage of the second part of the second memory cells is greater than a threshold voltage of the first part of the second memory cells.

9. A non-volatile memory, comprising:
a memory cell array comprising a plurality of memory cell strings, wherein each of the memory cell strings is coupled to a plurality of word lines; and
a controller coupled to the memory cell array and configured to:
perform a reading operation on a plurality of first memory cells of an Nth word line, and determine whether an equivalent threshold voltage of the first memory cells is greater than a preset threshold value to generate a determination result, wherein N is a positive integer greater than 0; and
decide whether to adjust at least one selected programming verification voltage of a plurality of programming verification voltages by an offset value according to the determination result in response to performing a programming operation on a plurality of second memory cells of an N+1th word line.

10. The non-volatile memory according to claim 9, wherein the controller completes a programming operation for a first part of the second memory cells of the N+1th word line before performing the reading operation on the first memory cells of the Nth word line.

11. The non-volatile memory according to claim 9, wherein the controller is further configured to:
read the first memory cells of the Nth word line by comparing current on bit lines of the first memory cells with a reference current to obtain whether the equivalent threshold voltage of the first memory cells is at a high threshold voltage state or a low threshold voltage state.

12. The non-volatile memory according to claim 11, wherein if the equivalent threshold voltage of the first memory cells is greater than the preset threshold value, the equivalent threshold voltage is at the high threshold voltage state; and if the equivalent threshold voltage of the first memory cells is not greater than the preset threshold value, the equivalent threshold voltage is at the low threshold voltage state.

13. The non-volatile memory according to claim 9, wherein the controller is further configured to:
lower the at least one selected programming verification voltage of the programming verification voltages by the offset value in response to the equivalent threshold voltage of the first memory cells being greater than the preset threshold value.

14. The non-volatile memory according to claim 13, wherein the controller is further configured to:
maintain the at least one selected programming verification voltage of the programming verification voltages unchanged in response to the equivalent threshold voltage of the first memory cells being not greater than the preset threshold value.

15. The non-volatile memory according to claim 10, wherein the controller is further configured to:
perform a programming operation on a second part of the second memory cells of the N+1th word line according to at least one adjusted programming verification voltage.

16. The non-volatile memory according to claim 15, wherein a threshold voltage of the second part of the second memory cells is greater than a threshold voltage of the first part of the second memory cells.

17. The non-volatile memory according to claim 9, wherein each of the memory cell strings is a NAND flash memory cell string.

18. The non-volatile memory according to claim 9, wherein each of the memory cell strings forms a columnar channel structure.
